(19) United States
(12) Patent Application Publication
(10) Pub. No.: US 2008/0244142 A1
(43) Pub. Date: Oct. 2, 2008

(54) Slot Device

(76) Inventors: Chih-Yuan Tu, Taipei (TW); Ming-Chih Hsu, Taipei (TW); Pei-Hua Sun, Taipei (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(21) Appl. No.: 12/061,219

(22) Filed: Apr. 2, 2008

(30) Foreign Application Priority Data
Apr. 2, 2007 (TW) 96111678

(51) Int. Cl. H05K 7/10

(52) U.S. Cl. 710/301

(57) ABSTRACT

A slot device has a slot, a determining circuit, and a warning device. The slot is used to install an expansion card. The determining circuit is coupled to the slot and is used to determine whether the expansion card is completely installed to the slot. The warning device is coupled to the determining circuit, and when the determining circuit determines that the expansion card is not completely installed to the slot, the determining circuit controls the warning device to send out a warning signal.

### RELATED APPLICATIONS

This application claims priority to Taiwan Application Serial Number 96111678, filed Apr. 2, 2007, which is herein incorporated by reference.

### BACKGROUND OF THE INVENTION

1. Field of the Invention

The invention relates to a slot device and, more particularly, to a computer slot device.

2. Description of the Related Art

The motherboard of a computer usually has a plurality of slots for installing various expansion cards to increase the efficiency and the function of the computer system. When an expansion card is not completely installed to a corresponding slot, it is possible that the system is incapable of normally being started or the corresponding function or efficiency cannot be increased.

At present, the method for determining the installation state of an expansion card on a slot are determining whether the expansion card is correctly inserted by visually detecting the appearance or whether the system can normally be started and whether the basic input output system (BIOS) has detected the expansion card. However, except the visual detecting method, other system detecting methods all need to repeat actions of starting and installing to ensure the installation state of the expansion card. The method for determining whether the expansion card is correctly inserted by visually detecting the appearance often causes wrong determination to occur because the installation distances between the expansion cards are very short or the interior space of the computer housing is too crowded, which causes the installation of the expansion card to fail.

Therefore, how to develop a new slot device which can actively detect the condition of an expansion card installed to the slot and can notify a user to avoid the repeated starting and installing actions has been the desire of present manufacturers and users.

### BRIEF SUMMARY OF THE INVENTION

The objective of the invention is to provide a slot device which is used to actively detect the condition of an expansion card installed to a slot and notify a user.

According to the above objective of the invention, a slot device is provided and has a slot, a determining circuit and a warning device. An expansion card can be installed to the slot and the determining circuit is coupled to the slot to determine whether the expansion card is completely installed to the slot. The warning device is coupled to the determining circuit, and when the determining circuit determines that the expansion card is not completely installed to the slot, the determining circuit controls the warning device to send out a warning signal.

Slot devices in a plurality of embodiments of the invention have a slot, a determining circuit and a warning device. The slot is used to install an expansion card and has an induction device which has a first sensing point and a second sensing point, and the first sensing point and the second sensing point are provided at two ends of the slot which are corresponding to the position where the expansion card is installed. The determining circuit is coupled to the first sensing point and the second sensing point and determines whether the expansion card is completely installed to the slot according to signals sent out by the sensing points. The warning device is coupled to the determining circuit, and when the determining circuit determines that the expansion card is not completely installed to the slot, the determining circuit controls the warning device to send out a warning signal.

The induction device in the slot is coupled to the determining circuit, and therefore, the determining circuit can determine the condition of the installed expansion card according to the signal outputted by the induction device and actively send out warning signals for some conditions. Therefore, the user can determine whether the expansion card is completely installed to the slot via the warning signal to avoid repeated starting and installing actions.

### BRIEF DESCRIPTION OF THE SEVERAL VIEWS OF THE DRAWINGS

These and other features, aspects, and advantages of the present invention will become better understood with regard to the following description, appended claims, and accompanying drawings.

FIG. 1 is a system schematic diagram showing the slot device of each embodiment of the invention.

FIG. 2 is a schematic diagram showing a slot device according to the first embodiment of the invention.

FIG. 3 is a schematic diagram showing a slot device according to the second embodiment of the invention.

FIG. 4 is a schematic diagram showing a slot device according to the third embodiment of the invention.

FIG. 5 is a schematic diagram showing a warning device of the embodiment of the invention.

FIG. 6 is a schematic diagram showing another warning device of the embodiment of the invention.

### DETAILED DESCRIPTION OF THE EMBODIMENTS

In each embodiment of the invention, the signal sent out by an induction device on a slot is utilized to determine the condition of an expansion card which is installed to a slot, and a warning device is controlled to send out a warning signal in a specific state. Persons having ordinary skill in the art can select an appropriate induction device and a corresponding determining method and a corresponding warning signal without departing from the spirit and the scope of the invention to cooperate with various consideration of cost and practical applications.

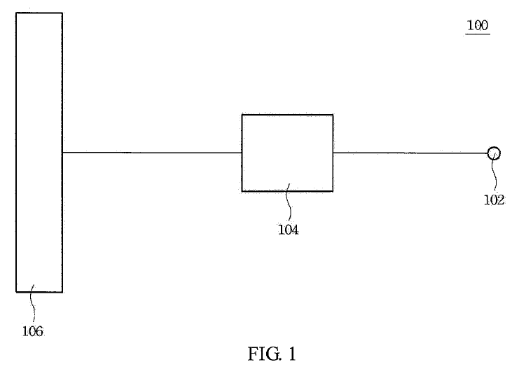

Please refer to FIG. 1 which is a system schematic diagram showing the slot device 100 of each embodiment of the invention. The slot device 100 has a slot 106, a determining circuit 104 and a warning device 102. The slot 106 is used to install an expansion card (not shown). The determining circuit 104 is coupled to the slot 106 and is used to determine the condition of the expansion card which is installed to the slot 106. The warning device 102 is coupled to the determining circuit 104, and when the determining circuit 104 determines that the expansion card is not completely installed to the slot 106, the determining circuit 104 controls the warning device 102 to send out a warning signal. The following will illustrate a plurality of embodiments as reference modes in practical applications, but they are not for limiting the invention.

### First Embodiment

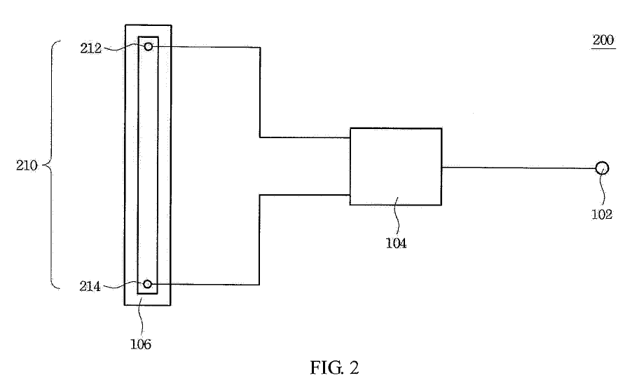

Please refer to FIG. 2 which is a schematic diagram showing a slot device 200 according to the first embodiment of the invention. The slot device 200 has a slot 106, a determining circuit 104 and a warning device 102. The slot 106 is used to install the expansion card and has an induction device 210. Since most conditions that expansion cards are not completely installed to slots are that one end of the expansion cards is not completely inserted into the slots, the induction device 210 has a first sensing point 212 and a second sensing point 214 which are provided at two ends of the slot 106 which are corresponding to the position where the expansion card is installed. In most conditions, the length of the slot 106 is set correspondingly to the length of the expansion card, and therefore, in the embodiment, the first sensing point 212 and the second sensing point 214 are disposed at two ends of the slot 106, respectively.

The determining circuit 104 is coupled to the first sensing point 212 and the second sensing point 214, and determines the condition of the expansion card installed to the slot 106 according to the signals sent out by the first sensing point 212 and the second sensing point 214. The warning device 102 is coupled to the determining circuit 104, and when the determining circuit 104 determines that the expansion card is not completely installed in the slot 106, the determining circuit 104 controls the warning device 102 to send out a warning signal. In the embodiment, the first sensing point 212 and the second sensing point 214 can be, for example, form as photo interrupters.

When the expansion card is completely installed in the slot 106, the photo interrupters are in a state that no light signal is detected. When no expansion card is installed in the slot 106, the photo interrupters are in a state that light signals have been detected. When one end of the expansion card is not completely inserted into the slot 106, and the other end of the expansion card is completely inserted into the slot 106, the photo interrupters are in different states. The determining circuit 104 determines the present installation condition of the expansion card according to the signals sent out by the photo interrupters in different states. When the determining circuit 104 determines that the expansion card is not completely inserted into the slot 106, the determining circuit 104 controls the warning device 102 to send out a warning signal.

### Second Embodiment

In the first embodiment, an optical detector as the induction device is installed in the slot to detect whether the expansion card is completely installed to the slot, but not only the above mode can be put into practice. And characteristics of each point in the slot can be utilized to achieve the same efficiency.

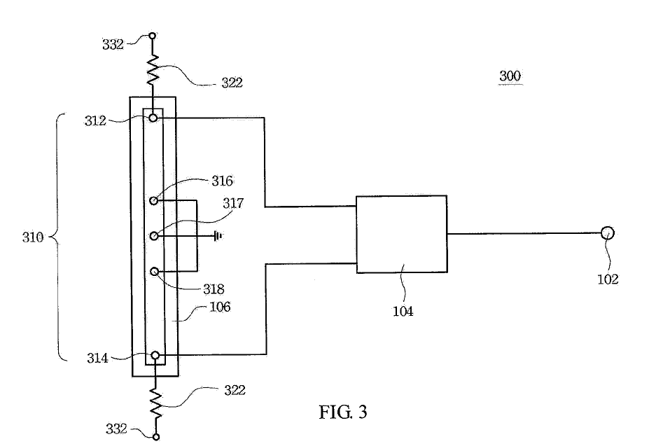

Please refer to FIG. 3 which is a schematic diagram showing a slot device 300 according to the second embodiment of the invention. Since the basic configuration of the embodiment is the same with the basic configuration of the first embodiment in substance, and then most components are not described for concise purpose.

Since a plurality of grounding points originally provided at the slot 106 must be connected to the grounding layer of a base plate, and all grounding points can form a grounding circuit on the expansion card after the expansion card is completely installed to the slot 106, the grounding points at the two ends of the slot 106 are floating as the first sensing point 312 and the second sensing point 314 of the induction device 310 in the embodiment. That is, the first sensing point 312 and the second sensing point 314 are floating in the slot 106, and are not directly connected to the grounding layer of the base plate when the expansion card is not installed, and only when the expansion card is completely installed to the slot 106, the first sensing point 312 and the second sensing point 314 can be in a grounding state via the grounding circuit formed by the expansion card and the other grounding points 316, 317 and 318.

In addition, the first sensing point 312 and the second sensing point 314 are connected to a voltage source 332 and a resistance 322 in series, respectively, to provide sufficient signal variety for the determining circuit 104 to determine the installation condition of the expansion card. Therefore, when the expansion card is completely installed to the slot 106, two floating is in the grounding state via the grounding circuit formed by the expansion card and the other grounding points 316, 317 and 318. When the expansion card is not completely installed to the slot 106, the voltages of voltage sources both can be measured at the two floating at this time. When one end of the expansion card is not completely installed to the slot 106, and the other end is completely installed to the slot 106, the two floating are in different states. The determining circuit 104 determines the present installation condition of the expansion card by determining whether the floating is connected to the ground via the grounding circuit. When the determining circuit 104 determines that the expansion card is not completely installed to the slot 106, the determining circuit 104 controls the warning device 102 to send out a warning signal.

### Third Embodiment

In some specific conditions such as that various expansion cards with different lengths can be installed in one slot, or various expansion cards with different lengths are designed under a single standard. The method which only utilizes the floating at the two ends of the slot and makes the signals of the grounding points higher cannot be applied in all conditions. At this time, a specific design can be made according to the definition of each pin in the electrical standard. For example, the peripheral component interconnect (PCI) express interface card and PCI express slot can solve the above problem via the grounding point and the PRSNT# point.

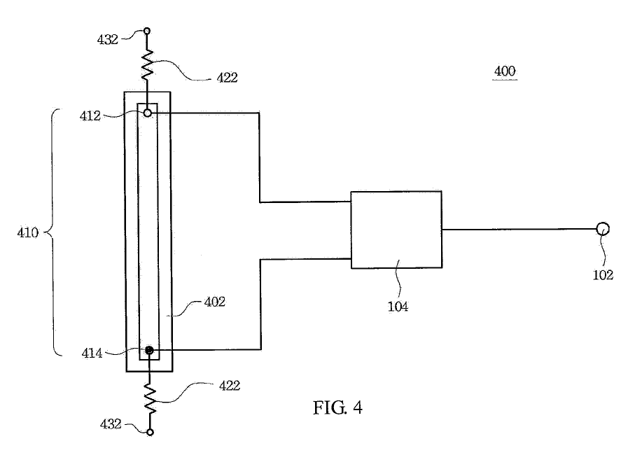

Please refer to FIG. 4 which is a schematic diagram showing a slot device 400 according to the third embodiment of the invention. At this time, a slot 402 is a PCI express slot, and the first sensing point 412 of an induction device 410 is a floating, and the second sensing point 414 of the induction device 410 is a PRSNT# point. The PCI express standard has various expansion cards with different lengths, such as X1, X4, X16 and so on. The design that the PRSNT# point must be located at the first point of the expansion card in the standard is utilized, and an another grounding point is cooperated, so that the first sensing point 412 and the second sensing point 414 can be disposed at two ends of the slot 402 which are corresponding to the position where the expansion card is installed to solve the problem brought about by various expansion cards with different lengths.

In addition, resistances 422 and voltage sources 432 are connected to the first sensing point 412 and the second sensing point 414 in series, respectively. Therefore, when the expansion card is completely installed to the slot 402, the two sensing points 412 and 414 are in the grounding state at this time. When the expansion card is not installed to the slot 402, the voltages of voltage sources can be measured at the two sensing points 412 and 414 at this time. When one end of the expansion card is not completely inserted into the slot 402, and the other end of the expansion card is completely inserted into the slot 402, the two sensing points 412 and 414 are in different states. The determining circuit 104 determines the present installation condition of the expansion card by determining whether the two sensing points 412 and 414 are in the grounding state. When the determining circuit 104 determines that the expansion card is not completely inserted into the slot 402, the determining circuit 104 controls the warning device 102 to send out a warning signal.

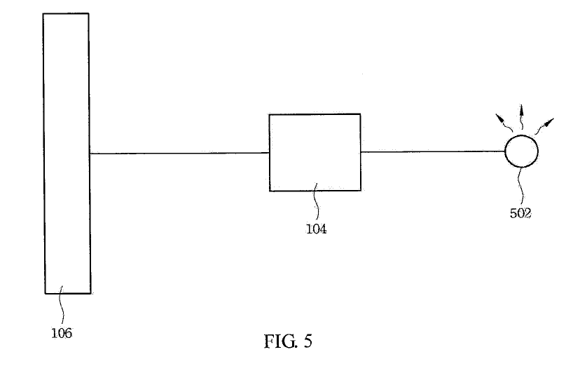

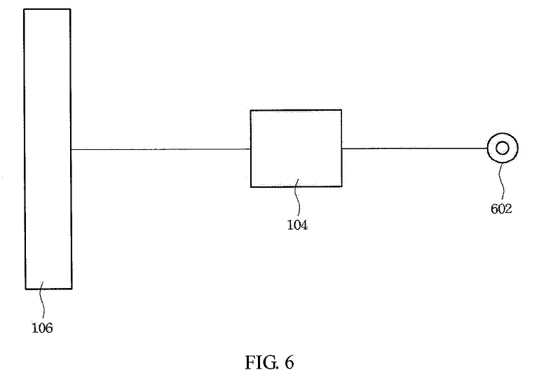

In each embodiment, the warning device can also have designs with various forms, and please refer to FIG. 5 and FIG. 6. In FIG. 5, a warning device 502 is a light emitting component and notifies a user the installation condition of an expansion card via a light signal. In FIG. 6, a warning device 602 is a buzzer and notifies a user the installation condition of an expansion card via an audio signal, and herein, the problem that for a long time, the user thinks of that the slot may be connected loosely only when the system cannot be started is solved.

Since the two sensing points are in the same states when no expansion card is installed to the slot or an expansion card is completely installed in the slot, the two sensing points send out the same signals to the determining circuit simultaneously. When one end of the expansion card is not completely installed in the slot, the states of the two sensing points are different, and then the two sensing points send out different signals to the determining circuit simultaneously. Therefore, an exclusive-or gate can be provided in the determining circuit and is cooperated with the control circuit of the warning device, and via the characteristic of the exclusive-or gate, whether the expansion card is completely installed to the slot is determined based on signal states of input terminals of the exclusive-or gate.

In addition, the slot can be a PCI slot, a memory slot, an accelerated graphics port (AGP) slot or an industry standard architecture (ISA) slot, and the embodiments can be applied in various slots to increase the convenience of installing various expansion cards to slots.

In each embodiment of the invention, the induction device in the slot is coupled to the determining circuit, and then the determining circuit can determine the installation condition of the expansion card according to the signals sent out by the induction device and actively sends out a warning signal. The user can know whether the expansion card is completely installed to the slot according to the warning signal to avoid repeated starting and installing actions.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A slot device comprising:
a slot for installing an expansion card;
a determining circuit which is coupled to the slot and is used to determine whether the expansion card is completely installed in the slot; and
a warning device coupled to the determining circuit, wherein when the determining circuit determines that the expansion card is not completely installed to the slot, the determining circuit controls the warning device to send out a warning signal.

2. The slot device according to claim 1, wherein an induction device is provided in the slot and is coupled to the determining circuit.

3. The slot device according to claim 2, wherein the induction device has a first sensing point and a second sensing point, and the first sensing point and the second sensing point are provided at two ends of the slot and are coupled to the determining circuit, respectively.

4. The slot device according to claim 3, wherein the first sensing point and the second sensing point are form as photo interrupters.

5. The slot device according to claim 3, wherein the first sensing point and the second sensing point are floating.

6. The slot device according to claim 5, wherein the first sensing point and the second sensing point are connected to a voltage source and a resistance in series, respectively.

7. The slot device according to claim 3, wherein the slot is a peripheral component interconnect (PCI) express slot, and the first sensing point and the second sensing point are a floating and a PRSNT# point, respectively.

8. The slot device according to claim 7, wherein the first sensing point and the second sensing point are connected to a voltage source and a resistance in series, respectively.

9. The slot device according to claim 1, wherein the slot is a PC[ slot, a memory slot, an accelerated graphics port (AGP) slot or an industry standard architecture (ISA) slot.

10. The slot device according to claim 1, wherein the warning device is a light emitting component or a buzzer.

11. A slot device comprising:
a slot for installing an expansion card, wherein the slot has an induction device, and the induction device has a first sensing point and a second sensing point which are provided at two ends of the slot which are corresponding to the position where the expansion card is installed;
a determining circuit which is coupled to the first sensing point and the second sensing point and is used to determine the condition of the expansion card which is installed to the slot by signals sent out by the first sensing point and the second sensing points; and
a warning device coupled to the determining circuit, wherein when the determining circuit determines that the expansion card is not completely installed to the slot, the determining circuit controls the warning device to send out a warning signal.

12. The slot device according to claim 11, wherein the first sensing point and the second sensing point are form as photo interrupters.

13. The slot device according to claim 11, wherein the first sensing point and the second sensing point are floating.

14. The slot device according to claim 13, wherein the first sensing point and the second sensing point are connected to a voltage source and a resistance in series, respectively.

15. The slot device according to claim 11, wherein the slot is a PCI express slot, and the first sensing point and the second sensing point are a floating and a PRSNT# point.

16. The slot device according to claim 15, wherein the first sensing point and the second sensing point are connected to a voltage source and a resistance in series, respectively.

17. The slot device according to claim 11, wherein the slot is a PCI slot, a memory slot, an AGP slot or an ISA slot.

18. The slot device according to claim 11, wherein the warning device is a light emitting component or a buzzer.
